(19) United States
(12) Patent Application Publication
(10) Pub. No.: US 2014/0256118 A1
(43) Pub. Date: Sep. 11, 2014

(54) METHOD FOR FORMING POLYSILICON USING HIGH ENERGY RADIATION SOURCE

(71) Applicant: EverDisplay Optronics (Shanghai) Limited, Shanghai (CN)

(72) Inventor: YuChun Yeh, Shanghai (CN)

(73) Assignee: EverDisplay Optronics (Shanghai) Limited, Shanghai (CN)

(21) Appl. No.: 14/150,464

(22) Filed: Jan. 8, 2014

(30) Foreign Application Priority Data
Mar. 8, 2013 (CN) 201310073478.2

(51) Int. Cl. H01L 21/02

(52) U.S. Cl. CPC H01L 21/02667; H01L 21/02592
USPC 438/487

(57) ABSTRACT

A method for forming polysilicon using high energy sources of radiation includes the steps of providing a laser system which has at least two laser sources with different wavelengths, a dichroic mirror, a reflecting mirror and a substrate; generating a laser beam by the laser sources to irradiate towards the substrate perpendicularly by the dichroic mirror and the reflecting mirror which are faced to the laser source and meet the laser sources at a certain angle; placing the reflecting mirror above the dichroic mirror; placing the a semiconductor thin-film material on the substrate. The advantages of the above technical solution are that as follows: the crystallization rate of poly-silicon is effectively increased; the usage frequency of the excimer laser is reduced; the cost thereof is reduced; the throughput of annealing is affectively improved.

### CROSS-REFERENCE TO RELATED APPLICATIONS

The present application claims priority to and the benefit of Chinese Patent Application No. CN 201310073478.2, filed on Mar. 8, 2013, the entire content of which is incorporated herein by reference.

### BACKGROUND OF THE INVENTION

1. Field of the Invention

The present disclosure relates to the technology of forming polysilicon, more specifically, to a method for forming polysilicon using the high energy sources of radiation.

2. Description of the Related Art

The instable crystallization ratio is a serious problem of the existing excimer laser annealing system.

A related art has discloses a method of forming a polycrystalline silicon thin film improved in crystallinity and a channel of a transistor superior in electrical characteristics by the use of such a polycrystalline silicon thin film. An amorphous silicon layer of a thickness preferably of 30 nm to 50 nm is formed on a substrate. Next, substrate heating is performed to set the amorphous silicon layer to preferably 350 DEG C. to 500 DEG C., more preferably 350 DEG C. to 450 DEG C. Then, at least the amorphous silicon layer is irradiated with laser light of an excimer laser energy density of 100 mJ/cm2 to 500 mJ/cm2, preferably 280 mJ/cm2 to 330 mJ/cm2, and a pulse width of 80 ns to 200 ns, preferably 140 ns to 200 ns, so as to directly anneal the amorphous silicon layer and form a polycrystalline silicon thin film. The total energy of the laser used for the irradiation of excimer laser light is at least 5 J, preferably at least 10 J.

Another related art has discloses a method of forming a poly-silicon pattern, including: forming an amorphous silicon pattern on a lower layer; forming a capping layer on the substrate covering the amorphous silicon pattern; poly-crystallizing the amorphous silicon pattern using an excimer laser annealing process; and removing the capping layer.

Another related art has discloses a method of fabricating a poly-Si thin film and a method of fabricating a poly-Si TFT using the same are provided. The poly-Si thin film is formed at a low temperature using ICP-CVD. After the ICP-CVD, ELA is performed while increasing energy by predetermined steps. A poly-Si active layer and a SiO2 gate insulating layer are deposited at a temperature of about 150 DEG C. using ICP-CVD. The poly-Si has a large grain size of about 3000 Å or more. A transistor having good electrical characteristics can be fabricated at a low temperature and thus can be formed on a heat tolerant plastic substrate.

Consequently, the above related arts may cause the instability of the crystallization ratio of the polysilicon.

### SUMMARY OF THE INVENTION

An embodiment of the present disclosure is directed toward a method for forming polysilicon using the high energy sources of radiation, which is capable of stabilizing the crystallization ratio of the polysilicon.

The method for forming polysilicon using the high energy sources of radiation, comprising: providing a laser system which comprises at least two laser sources with different wavelengths, a dichroic mirror, a reflecting mirror and a substrate; generating a laser beam by the laser sources to irradiate towards the substrate perpendicularly by the dichroic mirror and the reflecting mirror which are faced to the laser source and meet the laser sources at a certain angle; placing the reflecting mirror above the dichroic mirror; and placing a semiconductor thin-film material on the substrate.

According to one embodiment of the present disclosure, wherein the material of glass or plastic is adopted to manufacture the substrate.

According to one embodiment of the present disclosure, wherein the multilayer film structure is adopted to manufacture the semiconductor thin-film material.

According to one embodiment of the present disclosure, wherein the inorganic material is adopted to manufacture the semiconductor thin-film material.

According to one embodiment of the present disclosure, wherein the inorganic material includes the silicon nitride, silicon oxide and amorphous silicon.

According to one embodiment of the present disclosure, wherein the silicon nitride thin film is deposited on the substrate; the silicon oxide thin film is deposited on the surface of the silicon nitride thin film; the amorphous silicon thin film is deposited on the surface of the silicon oxide.

According to one embodiment of the present disclosure, wherein the technology of PVD, PECVD, LPCVD or ALD is adopted for depositing.

According to one embodiment of the present disclosure, wherein an UV-light source and a visible light source are adopted to form the two laser source respectively; the UV-light is emitted by the UV-light source; the visible light is emitted by the visible light source.

According to one embodiment of the present disclosure, wherein the wavelength of the UV-light source ranges from 157 nm to 355 nm.

According to one embodiment of the present disclosure, wherein the shape of the UV-light source is rectangle.

According to one embodiment of the present disclosure, wherein the UV-light source is a pulse light source.

According to one embodiment of the present disclosure, wherein the frequency of the UV-light source ranges from 50 Hz to 6000 Hz.

According to one embodiment of the present disclosure, wherein the pulse time of the UV-light source ranges from 10 ns to 100 ns.

According to one embodiment of the present disclosure, wherein the wavelength of the visible light is 523 nm, 527 nm or 532 nm.

According to one embodiment of the present disclosure, wherein the shape of the visible light source is rectangle.

According to one embodiment of the present disclosure, wherein the shape of the visible light source is 1.1 to 5 times of that of the UV-light source.

According to one embodiment of the present disclosure, wherein the shape of the visible light source is 1.1 to 5 times of that of the UV-light source.

According to one embodiment of the present disclosure, wherein the shape of the visible light source is 2 to 2.5 times of that of the UV-light source.

According to one embodiment of the present disclosure, wherein the shape of the visible light source is 2 to 2.5 times of that of the UV-light source.

According to one embodiment of the present disclosure, wherein the visible light is a continuous wave light source.

### BRIEF DESCRIPTIONS OF THE DRAWINGS

The accompanying drawings, together with the specification, illustrate exemplary embodiments of the present disclosure, and, together with the description, serve to explain the principles of the present disclosure.

FIG. 1 shows a structure diagram of the device for forming the polysilicon in the embodiment of the present disclosure;

FIG. 2 shows a structure diagram of the semiconductor film material which forms the polysilicon thin film.

### DETAILED DESCRIPTIONS

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximately estimated, meaning that the term “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

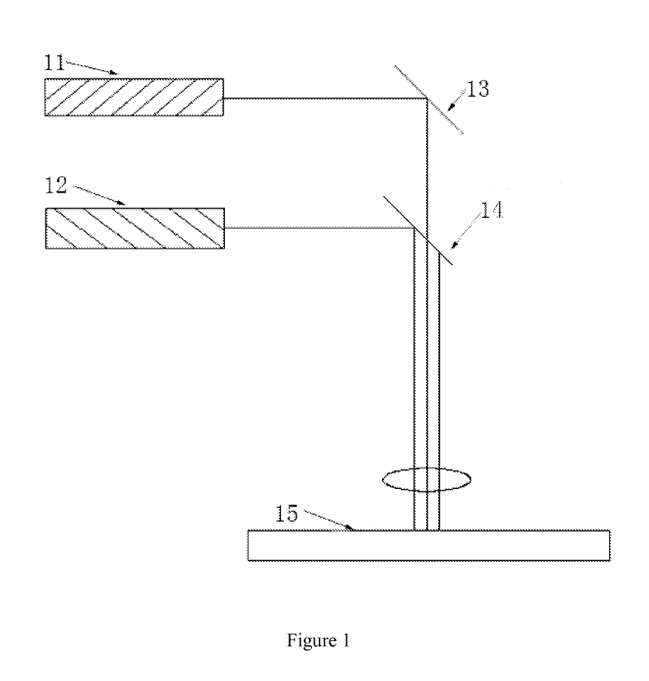

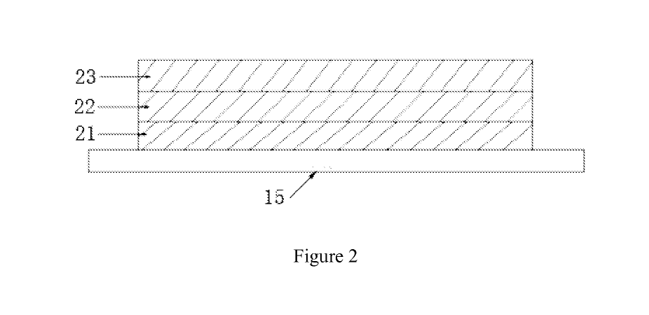

FIG. 1 shows a structure diagram of the device for forming the polysilicon in the embodiment of the present disclosure. The device is a laser system, including at least two high energy sources of radiation, a dichroic mirror, a reflecting mirror and a substrate, wherein the sources of radiation specifically are the laser sources. In the embodiment of the present disclosure, the laser source is respectively Excimer Laser Device 11 and Solid State Laser Device 12. Reflecting Mirror 13 faces towards Excimer Laser Device 11. Dichroic Mirror 14 faces towards Solid State Laser Device 12. Reflecting Mirror 13 is located above Dichroic Mirror 14. Dichroic Mirror 14 and Reflecting Mirror 13 meet the laser sources at a certain angle, consequently, the laser lights emitted by the two laser sources irradiates towards Substrate 15 perpendicularly, in the embodiment of the present disclosure, the angle is 45°. Substrate 15 can be formed by glass, plastic or any other material which can be suitable for forming the polysilicon. In the embodiment of the present disclosure, Substrate 15 is formed by glass. A semiconductor thin-film material is located on the substrate, and the laser emitted by the laser source irradiates towards the semiconductor film material on Substrate 15 perpendicularly. The material of the semiconductor film is the inorganic material with the multilayer film structure, and the inorganic material may be the silicon nitride, silicon oxide or amorphous silicon and so on. In the embodiment of the present disclosure, as shown in FIG. 2, the multilayer film structure is specifically formed by the following steps: a Silicon Nitride Thin Film 21 is formed on the surface of Substrate 15; next, a Silicon Oxide Thin Film 22 is formed on the surface of Silicon Nitride Thin Film 21; Finally, an Amorphous Silicon Thin Film 23 is formed on the surface of Silicon Oxide Thin Film 22. Thereby, a trilaminar semiconductor film structure is formed. PVD (Physical Vapor Deposition), PECVD (Plasma Enhanced Chemical Vapor Deposition), LPCVD (low pressure chemical vapor deposition, ALD (Atomic Layer Deposition) or other techniques are generally adopted in the art of depositing the inorganic thin film.

In the device for forming the polysilicon, two laser sources are two light sources of different wavelength, which can emit at least two lasers of different wavelength. In the embodiment of the present disclosure, the two laser sources emit visible light and UV-light respectively. The wavelength of the visible light is 523 nm, 527 nm and 532 nm. The wavelength of the UV-light ranges form 157 nm to 355 nm, such as, 157 nm, 193 nm, 253 nm, 308 nm, 351 nm and 355 nm. The UV-light and the visible light can be combined together by Dichroic Mirror 14 and Reflecting Mirror 13 and irradiate towards the semiconductor thin film of Substrate 15.

The shapes of the UV-light source and the visible light source are both rectangles. In the embodiment of the present disclosure, the shape of the visible light source is 1.1 to 5 times of that of the UV-light source. Specifically, the shape of the visible light source is 2 to 2.5 times of that of the UV-light source.

The UV-light source is a pulse light source. The frequency of the UV-light source ranges from 50 Hz to 6000 Hz. The pulse time thereof ranges form 10 ns to 100 ns. The visible light is a continuous wave light source. The UV-light and the visible light are combined together and irradiate towards the semiconductor thin film of Substrate 15. The semiconductor film absorbs the laser energy and then transforms to polysilicon.

While the present disclosure has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A method for forming a thin film comprising the steps of:
(a) providing a laser system with at least two laser sources of different wavelengths, a dichroic mirror, a reflecting mirror and a substrate;
(b) generating a laser beam by the laser sources to irradiate towards the substrate perpendicular to the dichroic mirror and the reflecting mirror which are faced to the laser source at an angle;
(c) placing the reflecting mirror above the dichroic mirror; and
(d) forming the thin-film on the substrate.

2. The method as disclosed in claim 1, wherein the substrate is made of glass or plastic.

3. The method as disclosed in claim 1, wherein the thin film is a multilayer film.

4. The method as disclosed in claim 3, wherein an inorganic material is adopted to manufacture the thin-film.

5. The method as disclosed in claim 4, wherein the inorganic material includes the silicon nitride, silicon oxide and amorphous silicon.

6. The method as disclosed in claim 5, wherein the silicon nitride is deposited on the substrate; the silicon oxide is deposited on surface of the silicon nitride thin film; the amorphous silicon is deposited on surface of the silicon oxide.

7. The method as disclosed in claim 6, wherein PVD, PECVD, LPCVD or ALD is adopted for depositing.

8. The method as disclosed in claim 1, wherein an UV-light source and a visible light source are adopted to form the two laser source respectively; UV-light is emitted by the UV-light source; visible light is emitted by the visible light source.

9. The method as disclosed in claim 8, wherein wavelength of the UV-light source ranges from 157 nm to 355 nm.

10. The method as disclosed in claim 9, wherein a shape of the UV-light source is rectangle.

11. The method as disclosed in claim 10, wherein the UV-light source is a pulse light source.

12. The method as disclosed in claim 11, wherein frequency of the UV-light source ranges from 50 Hz to 6000 Hz.

13. The method as disclosed in claim 12, wherein pulse time of the UV-light source ranges from 10 ns to 100 ns.

14. The method as disclosed in claim 8, wherein wavelength of the visible light is 523 nm, 527 nm or 532 nm.

15. The method as disclosed in claim 14, wherein a shape of the visible light source is rectangle.

16. The method as disclosed in claim 10, wherein a shape of the visible light source is 1.1 to 5 times of that of the UV-light source.

17. The method as disclosed in claim 15, wherein a shape of the visible light source is 1.1 to 5 times of that of the UV-light source.

18. The method as disclosed in claim 16, wherein a shape of the visible light source is 2 to 2.5 times of that of the UV-light source.

19. The method as disclosed in claim 17, wherein a shape of the visible light source is 2 to 2.5 times of that of the UV-light source.

20. The method as disclosed in claim 15, wherein the visible light is a continuous wave light source.
